(19) United States
(12) Patent Application Publication
(10) Pub. No.: US 2020/0212196 A1
(43) Pub. Date: Jul. 2, 2020

(54) SCHOTTKY ELECTRODE STRUCTURE AND SCHOTTKY DIODE AND MANUFACTURING METHOD THEREOF

(71) Applicant: Jiangsu CorEnergy Semiconductor Co. Ltd., Suzhou, Jiangsu (CN)

(72) Inventors: TINGGANG ZHU, Suzhou, Jiangsu (CN); TINGTING ZHANG, Suzhou, Jiangsu (CN); YIHENG LI, Suzhou, Jiangsu (CN)

(21) Appl. No.: 16/621,112

(22) PCT Filed: Oct. 16, 2017
(86) PCT No.: PCT/CN2017/106277

§ 371 Date: Dec. 10, 2019

(30) Foreign Application Priority Data
Aug. 28, 2017 (CN) 201710749630.2

(51) Int. Cl. H01L 29/66; H01L 29/06; H01L 27/092

(52) U.S. Cl. CPC H01L 29/66143; H01L 27/0928; H01L 29/0619

(57) ABSTRACT

Provided is a Schottky electrode structure, the electrode structure including: a first N-type semiconductor layer; a P-type semiconductor layer covering the first N-type semiconductor layer; a second N-type semiconductor layer or a semi-insulting semiconductor layer covering the P-type semiconductor layer. By using the Schottky electrode structure, the reverse withstand voltage of the diode can be effectively improved, and the reliability of the diode is effectively improved.

### CROSS-REFERENCE TO RELATED APPLICATIONS

This application claims priority to PCT Application No. PCT/CN2017/106277, having a filing date of Oct. 16, 2017, which is based on Chinese Application No. 201710749630.2, having a filing date of Aug. 28, 2017, the entire contents both of which are hereby incorporated by reference.

### FIELD OF TECHNOLOGY

The following relates to the field of semiconductor devices, in particular, to a Schottky electrode structure, a Schottky diode and a manufacturing method thereof.

### BACKGROUND

A Schottky diode is a diode in which a barrier is formed at a interface by using a metal to in contact with an N-type semiconductor. Since the Schottky diode does not have the process of accumulation and dissipation of minority carriers near the PN junction, the capacitance effect is very small and the working speed is very fast, which is especially suitable for high frequency or switching state applications.

However, since the depletion region of the Schottky diode is thin, the reverse breakdown voltage is relatively low. In the conventional art, when the Schottky diode is connected to the reverse voltage, an edge termination effect is usually generated at the edge of the connection between the anode metal and the N-type semiconductor, resulting in that a large amount of positive charge accumulates at the junction of the N-type semiconductor and the anode metal edge, that an electric field is generated in the same direction as the electric field generated by the reverse voltage, that the reverse voltage value to be withstood by the barrier region increases, and the Schottky diode is reversely breakdown. This is equivalent to indirectly reducing the reverse withstand voltage of the Schottky diode, reducing the reliability of the Schottky diode and affecting the normal operation of the circuit where the Schottky diode is located.

In the conventional art, at least the following problems exist: in the reverse state of the existing Schottky diode, due to the edge termination effect between the anode metal and the N-type semiconductor, a large amount of positive charge accumulates at the junction of the N-type semiconductor and the anode metal edge, and generate an electric field in the same direction as the electric field generated by the reverse voltage, resulting in that the reverse voltage value to be withstood by the barrier region increases, resulting in a reverse breakdown of the Schottky diode. This results in an indirect reduction in the reverse withstand voltage of the Schottky diode and a reduce in the reliability of the Schottky diode.

### SUMMARY

An aspect relates to a Schottky electrode structure, a Schottky diode and a manufacturing method thereof. It can effectively increase the breakdown voltage of the Schottky diode, and improve the reliability of the Schottky diode.

The embodiments of the present disclosure provide a Schottky electrode structure, a Schottky diode and a manufacturing method thereof, which are implemented as follows:

A Schottky electrode structure, comprises:

a first N-type semiconductor layer;
a P-type semiconductor layer covering the first N-type semiconductor layer; and
a second N-type semiconductor layer or a semi-insulating semiconductor layer covering the P-type semiconductor layer.

In a preferred embodiment, the P-type semiconductor layer and the second N-type semiconductor layer or the semi-insulating semiconductor layer are combined to form a heterojunction semiconductor layer provided with a through-channel formed by an etching process, and the through-channel penetrates into the P-type semiconductor layer or penetrates into a position within the first N-type semiconductor layer that is within 100 nanometers from an upper surface of the first N-type semiconductor layer.

In a preferred embodiment, the electrode structure further comprises an anode metal provided with a protrusion matching the through-channel, an edge portion of the anode metal is connected to the second N-type semiconductor layer or the semi-insulating semiconductor layer, the protrusion of the anode metal is connected to the first N-type semiconductor layer through the through-channel.

In a preferred embodiment, the edge portion of the anode metal is in contact with the first N-type semiconductor or the semi-insulating semiconductor layer, a lower surface of the protrusion of the anode metal is in contact with the bottom of the through-channel, and a side surface of the protrusion is in contact with an inner wall of the through-channel.

In a preferred embodiment, the bottom of the through-channel is provided with a P-type semiconductor protrusion of which a number is greater than or equal to 0.

A Schottky diode, comprises the Schottky electrode structure mentioned above, and further comprises:

a highly doped N-type semiconductor layer disposed under the first N-type semiconductor layer and in contact with the first N-type semiconductor layer;
a cathode metal disposed on an upper surface of the highly doped N-type semiconductor layer to form a ohmic contact with the highly doped N-type semiconductor layer; and
a substrate disposed under the highly doped N-type semiconductor layer and in contact with the highly doped N-type semiconductor layer.

In a preferred embodiment, a doping concentration of the highly doped N-type semiconductor layer is higher than that of the first N-type semiconductor layer.

A manufacturing method of the Schottky electrode structure described in the above embodiments, comprises:

providing a P-type semiconductor layer on an upper surface of a first N-type semiconductor layer;
providing a second N-type semiconductor layer or a semi-insulating semiconductor layer on an upper surface of the P-type semiconductor layer to obtain an initial structure of the Schottky electrode structure;
etching from an upper surface of the second N-type semiconductor layer or the semi-insulating semiconductor layer to form a through-channel, the through-channel penetrates into the P-type semiconductor layer or penetrates into a position within the first N-type semiconductor layer that is within 100 nanometers from the upper surface of the first N-type semiconductor layer;
providing an anode metal with a middle portion being a protrusion matching the through-channel;
connecting an edge portion of the anode metal to the second N-type semiconductor layer or the semi-insulating semiconductor layer, an edge portion of the anode metal is in contact with the second N-type semiconductor layer or the semi-insulating semiconductor layer; and connecting the protrusion to a bottom of the through-channel through the through-channel, a lower surface of the protrusion is in contact with the bottom of the through-channel, and a side surface of the protrusion is in contact with an inner wall of the through-channel.

By utilizing the Schottky electrode structure provided by the embodiments of the application, the P-type semiconductor layer and the second N-type semiconductor layer or the semi-insulating semiconductor layer form a heterojunction layer. When the diode is reversed, a built-in electric field is formed in the heterojunction, and the direction of the built-in electric field is opposite to the direction of the electric field formed by the positive charges accumulated near the junction point of the anode metal edge. Therefore, the built-in electric field can cancel out the electric field formed by the positive electric charge, thereby preventing the electric field formed by the positive electric charge from being superposed on the electric field formed by the reverse voltage and preventing the breakdown of the Schottky diode. In this way, it can indirectly increase the reverse withstand voltage value of the Schottky diode effectively and improve the reliability of the Schottky diode effectively. The Schottky diode provided by the present disclosure comprises the above mentioned Schottky electrode structure, and the reverse withstand voltage of the Schottky diode can be effectively improved, and the reliability of the diode is also effectively improved. By utilizing the manufacturing method of the Schottky electrode structure provided by the present disclosure, the above mentioned Schottky electrode structure can be manufactured, and the reverse withstand voltage property of the Schottky diode can be improved effectively.

### BRIEF DESCRIPTION

Some of the embodiments will be described in detail, with references to the following Figures, wherein like designations denote like members, wherein:

FIG. 1 is a schematic structural diagram of a Schottky electrode structure provided by one embodiment of the present disclosure;

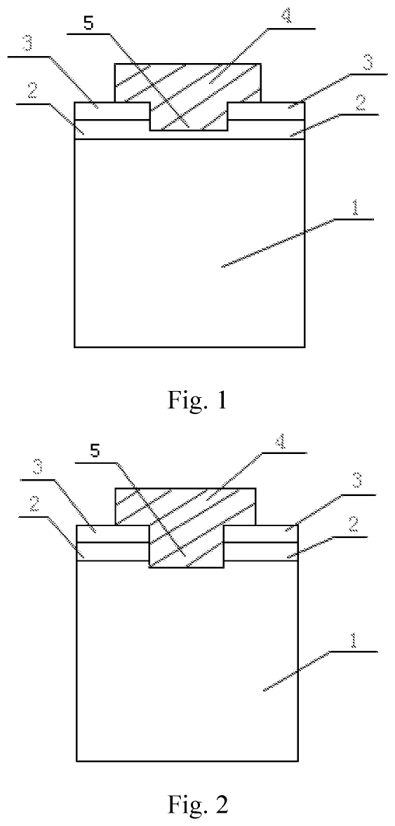

FIG. 2 is a schematic structural diagram of a Schottky electrode structure provided by another embodiment of the present disclosure;

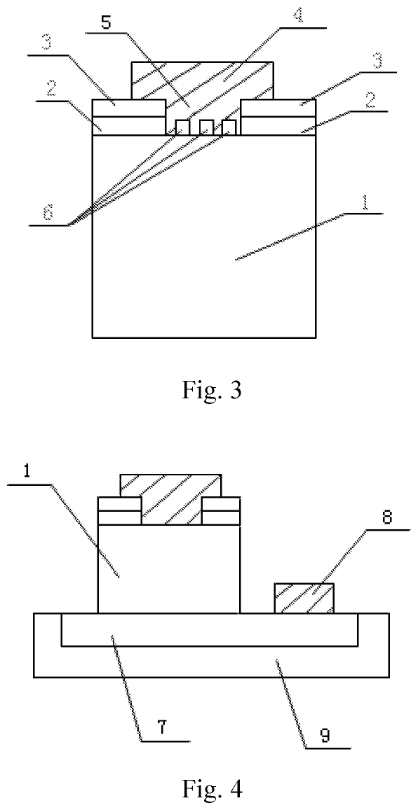

FIG. 3 is a schematic structural diagram of a Schottky electrode structure provided by yet another embodiment of the present disclosure;

FIG. 4 is a schematic structural diagram of a Schottky diode provided by one embodiment of the present disclosure;

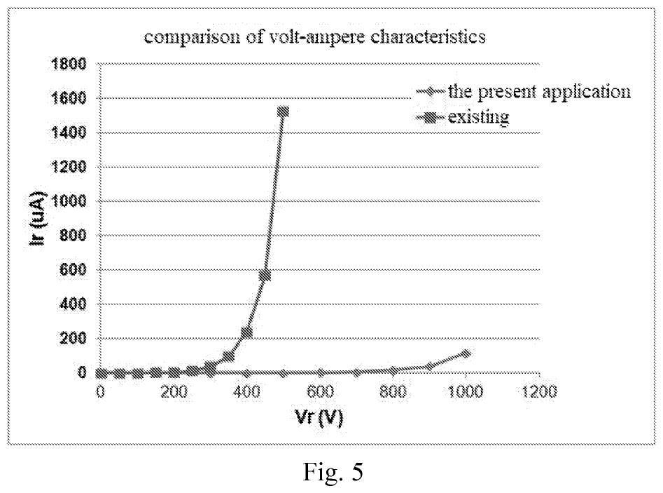

FIG. 5 is a comparison of volt-ampere characteristics of a Schottky diode provided by one embodiment of the present disclosure and an existing Schottky diode; and

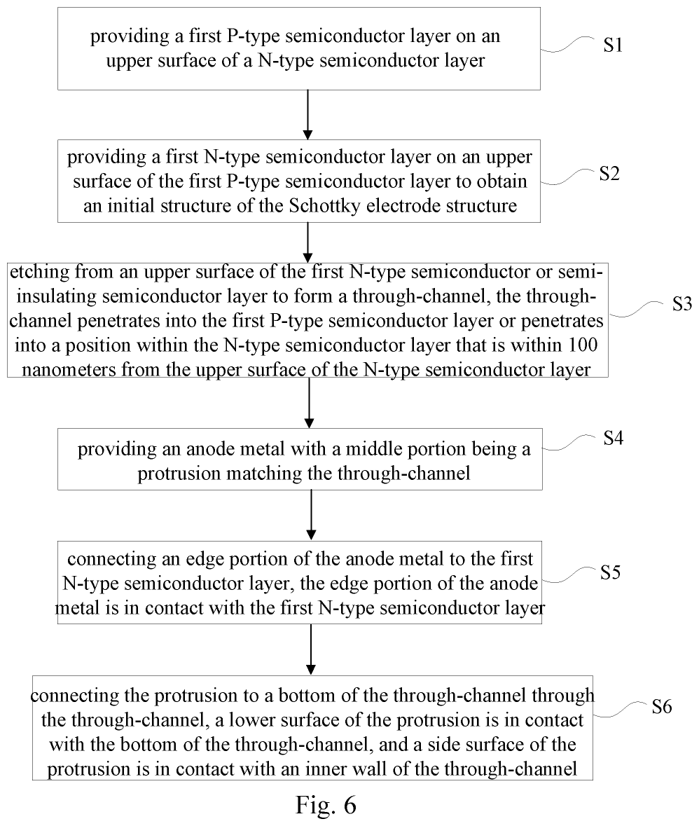

FIG. 6 is a schematic flow chart of a manufacturing method of the Schottky electrode structure provided by one embodiment of the present disclosure.

### DETAILED DESCRIPTION

The present disclosure provides a Schottky electrode structure, a Schottky diode and a manufacturing method thereof.

In order to enable those skilled in the art to better understand the technical solutions in the present disclosure, in the following, the embodiments of the present disclosure are explained clearly and fully combining with the accompanying drawings, and apparently, the described embodiments are merely a part of the embodiments of the present disclosure, not all of the embodiments. Based on the embodiments of the present disclosure, all other embodiments obtained by one of ordinary skill in the art without creative work belong to the protective scope of the present disclosure.

FIG. 1 is a schematic structural diagram of a Schottky electrode structure of the present disclosure. Although the present disclosure provides method operation steps or structures as shown in the following embodiments or drawings, more or fewer operation steps or structural units may be included in the method or structure based on conventional knowledge or without creative work. In the steps or the structures in which the necessary causal relationship does not exist logically, the performing sequence of the steps or the structure is not limited to the performing sequence or the module structure shown in the embodiments or the drawings of the present disclosure. When the method or structure is applied in practice, it may be performed sequentially or in parallel according to the method or structure shown in the embodiment or the drawings.

Specifically, as shown in FIG. 1, a Schottky electrode structure provided in an embodiment provided by the present disclosure may comprises:

a first N-type semiconductor layer 1;
a P-type semiconductor layer 2 covering the first N-type semiconductor layer 1; and
a second N-type semiconductor layer 3 or a semi-insulating semiconductor layer covering the P-type semiconductor layer 2.
Wherein, the first N-type semiconductor layer 1 may be N-type gallium nitride or N-type silicon carbide, of course, it may be another N-type semiconductor material commonly used for manufacturing diode.

The semi-insulating semiconductor layer may be a sin-type semiconductor, a weak N-type semiconductor, or a weak P-type semiconductor.

Wherein, the material composition of the P-type semiconductor layer 2 may be configured to be the same as the material composition of the first N-type semiconductor layer 1, for example, in one embodiment of the present disclosure, the first N-type semiconductor layer employs N-type gallium nitride, and the P-type semiconductor layer 2 employs P-type gallium nitride.

The material composition of the second N-type semiconductor layer 3 or the semi-insulating semiconductor layer may be configured to be the same as the material composition of the first N-type semiconductor layer 1, and also may be configured to be different. For instance, in one embodiment of the present disclosure, the first N-type semiconductor layer 1 employs N-type gallium nitride, and the second N-type semiconductor layer 3 or the semi-insulating semiconductor layer may also employ N-type gallium nitride. While in another embodiment of the present disclosure, the second N-type semiconductor layer 3 or a semi-insulating semiconductor layer may employ N-type aluminum gallium nitride.

In the present embodiment, as shown in FIG. 1, the P-type semiconductor layer and the second N-type semiconductor layer or the semi-insulating semiconductor layer are combined to form a heterojunction semiconductor layer provided with a through-channel formed by an etching process, and the through-channel penetrates into the P-type semiconductor layer or penetrates into a position within the first N-type semiconductor layer that is within 100 nanometers from an upper surface of the first N-type semiconductor layer.

The position within 100 nanometers includes a position 100 nanometers away from the upper surface of the first N-type semiconductor layer.

Wherein, the through-channel 5 is required to extend below the second N-type semiconductor layer 3 or the semi-insulating semiconductor layer, and meanwhile a bottom surface of the through-channel 5 may be disposed on a lower surface of the P-type semiconductor layer 2.

Alternatively, in another embodiment of the present disclosure, as shown in FIG. 2, the bottom surface of the through-channel 5 may be located within the first N-type semiconductor layer 1, however, the bottom surface of the through-channel 5 cannot exceed 100 nanometers from the upper surface of the first N-type semiconductor layer 1.

FIG. 3 is a schematic structural diagram of yet another Schottky electrode structure provided by an embodiment of the present disclosure, as shown in FIG. 3, the bottom surface of the through-channel 5 may provided with a P-type semiconductor protrusion of which a number is greater than or equal to 0.

Exemplarily, in FIG. 3, three P-type semiconductor protrusions are provided, of course, in other embodiments of the present disclosure, the number of the P-type semiconductor protrusions is not limited, and may be four, five, six, and so on, and maybe no P-type semiconductor protrusion is provided.

As shown in FIGS. 1, 2 and 3, the Schottky electrode structure in the respective embodiments mentioned above further comprises an anode metal 4, the anode metal 4 is provided with a protrusion matching the through-channel 5 in the middle, an edge portion of the anode metal 4 is connected to the second N-type semiconductor layer 3 or the semi-insulating semiconductor layer, and the protrusion of the anode metal 4 is connected to the first N-type semiconductor layer 1 through the through-channel 5. The edge portion of the anode metal 4 is in contact with the second N-type semiconductor layer 3 or a semi-insulating semiconductor layer, a lower surface of the protrusion of the anode metal 4 is in contact with the bottom of the through-channel 5, and a side surface of the protrusion is in contact with an inner wall of the through-channel 5.

In the above respective embodiments, one heterojunction layer is exemplarily employed. In other embodiments of the present disclosure, the upper surface of the first N-type semiconductor layer 1 may be provided with more than one heterojunction layer, specifically, the number of the heterojunction layer is not limited in the present disclosure, the heterojunction layer may be repeatedly disposed on the upper surface of the first N-type semiconductor layer 1, for example, another P-type semiconductor layer is further disposed on the second N-type semiconductor layer 3 or the semi-insulating semiconductor layer, and another second N-type semiconductor layer or another semi-insulating semiconductor layer is provided on the another P-type semiconductor layer, and further, yet another P-type semiconductor layer may be provided, . . . , herein will not list them all. Correspondingly, the through-channel still extends into the P-type semiconductor layer or the first N-type semiconductor layer.

By utilizing the implementation of the Schottky electrode structure provided by the above embodiments, the P-type semiconductor layer and the second N-type semiconductor layer or the semi-insulating semiconductor layer form a heterojunction layer. When the diode is reversed, a built-in electric field is formed in the heterojunction, and the direction of the built-in electric field is opposite to the direction of the electric field formed by the positive charges accumulated near the junction point of the anode metal edge. Therefore, the built-in electric field can cancel out the electric field formed by the positive electric charge, thereby preventing the electric field formed by the positive electric charge from being superposed on the electric field formed by the reverse voltage and preventing the breakdown of the Schottky diode. In this way, it can indirectly increase the reverse withstand voltage value of the Schottky diode effectively and improve the reliability of the Schottky diode effectively.

FIG. 4 is a schematic structural diagram of a Schottky diode provided by an embodiment of the present disclosure, and the Schottky diode may comprises the Schottky electrode structure of the above respective embodiments, and may further comprises:

a highly doped N-type semiconductor layer 7 disposed under the first N-type semiconductor layer 1 and in contact with the first N-type semiconductor layer 1;
a cathode metal 8 disposed on an upper surface of the highly doped N-type semiconductor layer 7 to form an ohmic contact with the highly doped N-type semiconductor layer 7; and
a substrate 9 disposed under the highly doped N-type semiconductor layer 7 and in contact with the highly doped N-type semiconductor layer 7.

In the present embodiment, a doping concentration of the highly doped N-type semiconductor layer is higher than that of the first N-type semiconductor layer, in general, the doping concentration of the highly doped N-type semiconductor layer is one time higher than that of the first N-type semiconductor layer 1, of course, the present disclosure does not limit the specific value.

Wherein, the substrate 9 is generally a sapphire substrate, and of course, the specific composition of the substrate is not limited herein.

The Schottky diode of the above embodiment comprises the above mentioned Schottky electrode structure, and the reverse withstand voltage of the Schottky diode is effectively improved, and the reliability of the diode is also effectively improved.

FIG. 5 is a comparison of volt-ampere characteristics of the Schottky diode before and after using the Schottky electrode structure in an example of the present disclosure.

As shown in FIG. 5, the curve corresponding to the square scatter is the volt-ampere characteristic curve of the existing Schottky diode, and the curve corresponding to the diamond scatter is the volt-ampere characteristic curve of the Schottky diode employing the Schottky electrode structure provided by the embodiments of the present disclosure, and in FIG. 5, the horizontal axis Vr (V) represents the reverse voltage, and the vertical axis Ir (uA) represents the leakage current. It can be seen that the existing Schottky diode exhibits a leakage current of more than 1500 microamps at around 500 volts, and the Schottky diode using the Schottky electrode structure described in the present disclosure exhibits a leakage current of only about 100 microamps at 1000 volts. It can be proved that when using the Schottky electrode structure of the present disclosure, the reverse withstand voltage value of the Schottky diode is significantly improved, and the reverse withstand voltage characteristic of the Schottky diode is remarkably enhanced.

Based on the Schottky electrode structure described in the above embodiments, the present disclosure further provides a manufacturing method of the Schottky electrode structure, and FIG. 6 is a schematic flowchart of the manufacturing method of an embodiment of the present disclosure, specifically, as shown in FIG. 4, the method may comprises:

S1: providing a P-type semiconductor layer on an upper surface of a first N-type semiconductor layer.

The specific process for providing the P-type semiconductor layer is not limited in the present disclosure, for example, the P-type semiconductor layer may be disposed by a process such as thermal growth, deposit, or the like. Of course, the implementer can also configure the P-type semiconductor layer using other common semiconductor manufacturing processes. Just that the P-type semiconductor layer can be effectively in contacted with and fixed on the surface of the N-type semiconductor.

S2: providing a second N-type semiconductor layer or a semi-insulating semiconductor layer on an upper surface of the P-type semiconductor layer to obtain an initial structure of the Schottky electrode structure.

Wherein, the specific process for providing the second N-type semiconductor layer or the semi-insulating semiconductor layer is not limited in the present disclosure, just that the second N-type semiconductor layer or the semi-insulating semiconductor layer can be effectively in contacted with and fixed on the surface of the first P-type semiconductor.

S3: etching from an upper surface of the second N-type semiconductor layer or the semi-insulating semiconductor layer to form a through-channel, the through-channel penetrates into the P-type semiconductor layer or penetrates into a position within the first N-type semiconductor layer that is within 100 nanometers from the upper surface of the first N-type semiconductor layer.

Wherein, the etching may be selected from wet etching, dry etching, or other etching processes commonly used in the field of semiconductor manufacturing, and specifically, the implementer may determine the etching process according to actual process conditions.

S4: providing an anode metal with a middle portion being a protrusion matching the through-channel.

S5: connecting an edge portion of the anode metal to the second N-type semiconductor layer or the semi-insulating semiconductor layer, the edge portion of the anode metal is in contact with the second N-type semiconductor layer or the semi-insulating semiconductor layer.

S6: connecting the protrusion to a bottom of the through-channel through the through-channel, a lower surface of the protrusion is in contact with the bottom of the through-channel, and a side surface of the protrusion is in contact with an inner wall of the through-channel. By utilizing the above mentioned method, the Schottky electrode structure can be manufactured effectively, and the reverse withstand voltage property of the Schottky diode can be improved effectively.

Although the different processing of the Schottky electrode structure is mentioned in the present disclosure, various timing modes, processes/processing/connection methods and the like from providing the P-type semiconductor layer, providing the second N-type semiconductor layer or the semi-insulating semiconductor layer, configuring the middle portion of the cathode metal to be a protrusion matching the through-channel, connecting, and connecting the edge portion of the cathode metal to the second N-type semiconductor layer or the semi-insulating semiconductor layer, to extending the protrusions to the first N-type semiconductor layer through the through-channel, are described, but the present disclosure is not limited to the case described in the industry standard or the embodiments, and the implementations according to some industry standards or using a custom manner or slightly modified implementations based on the implementations described in the embodiments may also achieve a same, equivalent or similar implementation effect, or a predictable implementation effect after modification. The application of these modified embodiments may still fall within the scope of alternative embodiments of the present disclosure.

Although the present disclosure provides method operation steps as described in the embodiments or the flowchart, more or fewer operation steps may be included based on conventional or non-creative means. The order of the steps listed in the embodiments is only one of various preforming sequence of the steps, and does not represent the only preforming sequence. When preforming in practice, the method may be performed sequentially or in parallel according to the embodiment or the drawings. The terms“comprise”, “include” or any other variants are intended to cover non-exclusive inclusions, such that a process, method, product, or device that comprises a plurality of elements includes not only those elements but also other elements not specifically listed or elements inherent in the process, method, product or device. In the absence of further limitations, it is not excluded that there are additional identical or equivalent elements in the process, method, product, or device comprising the elements.

The various embodiments in the specification are described in a progressive manner, and the same or similar parts of the various embodiments may be referred to each other, and each of the embodiments focuses on differences from other embodiments.

Although the present invention has been disclosed in the form of preferred embodiments and variations thereon, it will be understood that numerous additional modifications and variations could be made thereto without departing from the scope of the invention.

For the sake of clarity, it is to be understood that the use of ‘a’ or ‘an’ throughout this application does not exclude a plurality, and ‘comprising’ does not exclude other steps or elements.

1. A Schottky electrode structure, comprising:
a first N-type type semiconductor layer;
a P-type semiconductor layer covering the first N-type semiconductor layer; and
a second N-type semiconductor layer or a semi-insulating semiconductor layer covering the P-type semiconductor layer.

2. The Schottky electrode structure according to claim 1, wherein the P-type semiconductor layer and the second N-type semiconductor layer or the semi-insulting semiconductor layer are combined to form a heterojunction semiconductor layer provided with a through-channel formed by an etching process, and the through-channel penetrates into the P-type semiconductor layer or penetrates into a position within the first N-type semiconductor layer that is within 100 nanometers from an upper surface of the first N-type semiconductor layer.

3. The Schottky electrode structure according to claim 1, further comprising an anode metal provided with a protrusion matching the through-channel, an edge portion of the anode metal is connected to the second N-type semiconductor layer or the semi-insulting semiconductor layer, wherein the protrusion of the anode metal is connected to a bottom of the through-channel through the through-channel.

4. The Schottky electrode structure according to claim 3, wherein the edge portion of the anode metal is in contact with the second N-type semiconductor layer or the semi-insulting semiconductor layer, a lower surface of the protrusion of the anode metal is in contact with the bottom of the through-channel, and a side surface of the protrusion is in contact with an inner wall of the through-channel.

5. The Schottky electrode structure according to claim 2, wherein a bottom of the through-channel is provided with a P-type semiconductor protrusion of which a number is greater than or equal to 0.

6. A Schottky diode comprising the Schottky electrode structure according to claim 1, and further comprising:
a highly doped N-type semiconductor layer disposed under the first N-type semiconductor layer and in contact with the first N-type semiconductor layer;
a cathode metal disposed on an upper surface of the highly doped N-type semiconductor layer to form an ohmic contact with the highly doped N-type semiconductor layer; and
a substrate disposed under the highly doped N-type semiconductor layer and in contact with the highly doped N-type semiconductor layer.

7. The Schottky diode according to claim 6, wherein a doping concentration of the highly doped N-type semiconductor layer is higher than that of the first N-type semiconductor layer.

8. A manufacturing method of the Schottky electrode structure according to claim 1, comprising:
providing the P-type semiconductor layer on an upper surface of the first N-type semiconductor layer;
providing the first second N-type semiconductor layer or a semi-insulating semiconductor layer on an upper surface of the P-type semiconductor layer to obtain an initial structure of the Schottky electrode structure;
etching from an upper surface of the second N-type semiconductor layer or the semi-insulting semiconductor layer to form a through-channel, the through-channel penetrates into the P-type semiconductor layer or penetrates into a position within the first N-type semiconductor layer that is within 100 nanometers from the upper surface of the first N-type semiconductor layer;
providing an anode metal with a middle portion being a protrusion matching the through-channel;
connecting an edge portion of the anode metal to the second N-type semiconductor layer or the semi-insulating semiconductor layer, an edge portion of the anode metal is in contact with the second N-type semiconductor layer or the semi-insulating semiconductor layer; and
connecting the protrusion to a bottom of the through-channel through the through-channel, a lower surface of the protrusion is in contact with the bottom of the through-channel, and a side surface of the protrusion is in contact with an inner wall of the through-channel.
